(19) United States
(12) Patent Application Publication
(10) Pub. No.: US 2012/0125425 A1
(43) Pub. Date: May 24, 2012

(54) COMPOUND SEMICONDUCTOR SOLAR CELL AND METHOD OF MANUFACTURING THE SAME

(75) Inventors: Dae-Hyung Cho, Seoul (KR); Yong-Duck Chung, Daejeon (KR)

(73) Assignee: ELECTRONICS AND TELECOMMUNICATIONS RESEARCH INSTITUTE, Daejeon (KR)

(21) Appl. No.: 13/191,820

(22) Filed: Jul. 27, 2011

(30) Foreign Application Priority Data
Nov. 19, 2010 (KR) 10-2010-0115710

(51) Int. Cl. H01L 31/0216; H01L 31/18

(52) U.S. Cl. 136/256; 438/95; 257/E31.027

(57) ABSTRACT

Provided is a compound semiconductor solar cell. The compound semiconductor solar cell includes: an impurity diffusion preventing layer disposed on a substrate, added with an alkali component, and formed of a metal layer of one of Cr, Co, or Cu; a rear electrode disposed on the impurity diffusion preventing layer and formed of Mo; a CIGS based light absorbing layer disposed on the rear electrode; and a front transparent electrode disposed on the light absorbing layer.

### CROSS-REFERENCE TO RELATED APPLICATIONS

This U.S. non-provisional patent application claims priority under 35 U.S.C. §119 of Korean Patent Application No. 10-2010-0115710, filed on Nov. 19, 2010, the entire contents of which are hereby incorporated by reference.

### BACKGROUND OF THE INVENTION

The present invention disclosed herein relates to a compound semiconductor solar cell and a method of manufacturing the same, and more particularly, to a CIGS based thin film solar cell and a method of manufacturing the same.

Due to the shortage of silicon raw material according to market growth of a solar cell, an interest in a thin film solar cell increases. Based on materials, the thin film solar cell is divided in to an amorphous or crystalline silicon thin film solar cell, a CIGS based thin film solar cell, a CdTe thin film solar cell, and a dye-sensitized solar cell. The CIGS based thin film solar cell includes a light absorbing layer, which is formed of a representative GROUP I-III-VI₂ compound semiconductor and has a direct transition type energy bandgap and a high light absorption coefficient. Thus, a high efficient solar cell may be manufactured with a thin film of about 1 μm to about 2 μm.

The CIGS based solar cell has efficiency that is higher than that of the commercialized amorphous silicon and CdTe thin film solar cell and close to that of a typical polycrystalline silicon solar cell. Moreover, the CIGS based solar cell is formed of a cheaper, more flexible material, and less performance deterioration for a long time than other kinds of solar cell materials.

### SUMMARY OF THE INVENTION

The present invention provides a compound semiconductor solar cell with improved efficiency.

The present invention also provides a compound semiconductor solar cell with reduced manufacturing costs and improved efficiency.

Embodiments of the present invention provide compound semiconductor solar cells including: an impurity diffusion preventing layer disposed on a substrate, added with an alkali component, and formed of a metal layer of one of Cr, Co, or Cu; a rear electrode disposed on the impurity diffusion preventing layer and formed of Mo; a CIGS based light absorbing layer disposed on the rear electrode; and a front transparent electrode disposed on the light absorbing layer.

In some embodiments, the alkali component may be at least one of Li, Na, K, Rb, Cs, Fr, N, P, As, Sb, Bi, V, Nb, and Ta.

In other embodiments, a content of the alkali component added to the impurity diffusion preventing layer may be about 0.1 atomic % to about 50 atomic % to a total weight of the metal layer.

In still other embodiments, the impurity diffusion preventing layer may have a thickness of about 0.01 μm to about 10 μm.

In even other embodiments, the light absorbing layer may be formed of a GROUP I-III-VI2 compound semiconductor.

In yet other embodiments, the light absorbing layer may include the alkali component diffusing from the impurity diffusion preventing layer.

In further embodiments, the substrate may be one of a sodalime glass substrate, a ceramic substrate, a metal substrate, and a polymer film.

In still further embodiments, the compound semiconductor solar cells may further include a buffer layer between the light absorbing layer and the front transparent electrode.

In even further embodiments, the compound semiconductor solar cells may further include: an anti-reflection layer disposed in one region on the front transparent electrode; and a grid electrode disposed at a side of the anti-reflection layer in contact with the front transparent electrode.

In other embodiments of the present invention, methods of manufacturing a compound semiconductor solar cell include: forming an impurity diffusion preventing layer disposed on a substrate, added with an alkali component, and formed of a metal layer of one of Cr, Co, and Cu; forming a rear electrode disposed on the impurity diffusion preventing layer and formed of Mo; forming a CIGS based light absorbing layer disposed on the rear electrode; and forming a front transparent electrode disposed on the light absorbing layer.

In some embodiments, the impurity diffusion preventing layer may be formed through a sputtering method.

In other embodiments, the rear electrode may be formed through the sputtering method in the same chamber as the impurity diffusion preventing layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a sectional view illustrating a CIGS series thin film solar cell according to an embodiment of the present invention;

FIGS. 2A through 2G are sectional views illustrating a method of manufacturing a CIGS based thin film solar cell according to an embodiment of the present invention; and

FIG. 3 is a flowchart illustrating a method of manufacturing a CIGS based thin film solar cell according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the dimensions of layers and regions are exaggerated for clarity of illustration. Like reference numerals refer to like elements throughout.

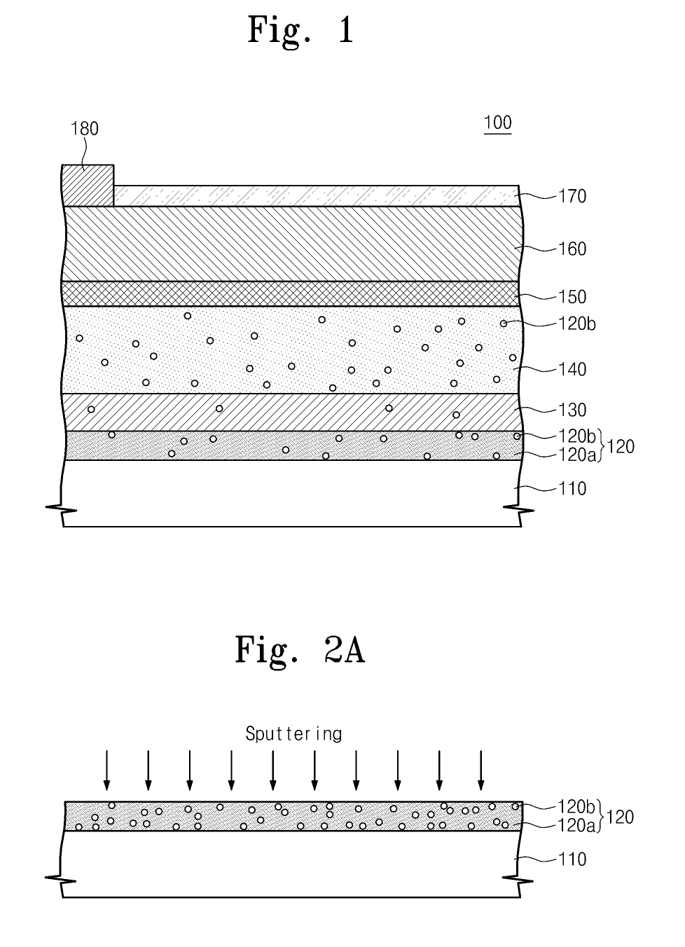

FIG. 1 is a sectional view illustrating a CIGS series thin film solar cell according to an embodiment of the present invention.

Referring to FIG. 1, the CIGS based thin film solar cell 100 may include a substrate 100 and an impurity diffusion preventing layer 120, a rear electrode 130, a CIGS based light absorbing layer 140, a buffer layer 150, a front transparent electrode 160, an anti-reflection layer 170, and a grid electrode 180, which are sequentially stacked on the substrate 110.

The substrate 110 may be a sodalime glass substrate. The sodalime glass substrate is known as a relatively cheap substrate material. Additionally, natrium (Na) of the sodalime glass substrate 100 diffuses into the CIGS based light absorbing layer 140 to improve photoelectric conversion efficiency of the solar cell 100.

Differently, the substrate 110 may be a ceramic substrate such as alumina (Al₂O₃) and quartz, a metal substrate such as stainless steel, Cu tape, Cr steel, Kovar (i.e., an alloy of Ni and Fe), Ti, ferritic steel, and Mo, or a polymer film such as a Kapton, polyester or polyimide film (e.g., Upilex, ETH-PI). The substrate 110 may typically use the sodalime glass substrate where an alkali component such as Na may diffuses into the light absorbing layer 140 during the manufacturing of the CIGS based light absorbing layer 140, but the present invention is not limited to the sodalime glass substrate with an alkali component 120b in the impurity diffusion preventing layer 120 and may use a substrate without the alkali component 120b.

The impurity diffusion preventing layer 120 may serve to prevent impurity from diffusing from a supply source of the alkali component 120b and the substrate 110 to the light absorbing layer 140.

As one example, the impurity diffusion preventing layer 120 may be formed of a metal layer 120a for preventing impurity diffusion with the alkali component 120b. The stainless steel used typically for a flexible substrate contains an impurity such as Fe and, since Mo used for the rear electrode 130 may not prevent the impurity from diffusing into the light absorbing layer 140 during a manufacturing process of the light absorbing layer 140, the impurity diffusion preventing layer 120 may be interposed. Especially, it may expect to some extent that the thick thickness of Mo may prevent impurity diffusion, but due to its expensive price, it is undesirable when considering manufacturing costs.

The metal layer 120a may include one of Cr, Co, and Cu. Cr, Co, and Cu are relatively cheaper than Mo and have excellent impurity diffusion preventing function to thickness.

The alkali component 120b may be at least one of Li, Na, K, Rb, Cs, Fr, N, P, As, Sb, Bi, V, Nb, and Ta. The alkali component 120b may be appropriately selected in consideration of manufacturing cost, crystalline relationship to the CIGS based light absorbing layer 140, and activation as impurity. The alkali component 120b may be Li, Na or K, and Na is more preferable. The alkali component 120 may diffuse into the light absorbing layer 140 to increase photoelectric conversion efficiency of the CIGS based thin film solar cell 100. This is because the alkali component 120b forms an organization of the CIGS thin film better, serves as a protective layer in a grain boundary, improves p-type electrical conductivity, and reduces defects of the CIGS thin film.

The impurity diffusion preventing layer 120 may be formed of a thickness of about 0.01 μm to about 10 μm to prevent impurity from diffusing from the substrate 110 and realize a thin film solar cell.

The content of the alkali component 120b added to the impurity diffusion preventing layer 120 may vary according to a thickness, composition, and manufacturing process of the light absorbing layer 140. If the alkali component 120b added to the impurity diffusion preventing layer 120 is excessive, the alkali component 120b may serve as an impurity so that interlayer adhesion and efficiency of the solar cell 100 may be deteriorated. On the other hand, if the alkali component 120b added to the impurity diffusion preventing layer 120 is too little, desirable crystal growth to the CIGS thin layer and efficiency improvement of the solar cell 100 may not be obtained. Accordingly, the content of the alkali component 120b added to the impurity diffusion preventing layer 120 may be about 0.1 atom % to about 50 atom % to the total weight of the metal layer 120a.

The rear electrode 130 may have low resistivity and excellent formation characteristic of ohmic contact with the CIGS based light absorbing layer 140. Preferably, the rear electrode 130 may be formed of Mo. Mo has high temperature stability under high electrical conductivity and Se atmosphere, and a de-lamination phenomenon does not occur due to a difference of a thermal expansion coefficient with respect to the CIGS based light absorbing layer 140.

The light absorbing layer 140 may be formed of a GROUP I-III-VI₂ compound semiconductor. The GROUP I-III-VI₂ compound semiconductor may be a chalcopyrite based compound semiconductor such as CuInSe, CuInSe₂, CuInGaSe, CuInGaSe₂, AgCuInGaSe₂, AgCuInGaSe₂, CuInGaSSe₂, and CuInGaS₂. These compound semiconductors may be commonly named as CIGS based thin films.

Preferably, the light absorbing layer 140 may be formed of CuInGaSe₂, which has an energy bandgap of about 1.2 eV close to the maximum efficiency of a polycrystalline solar cell of a typical wafer form in a single bonding solar cell. The light absorbing layer 140 may include the alkali component 120b diffusing into the impurity diffusion preventing layer 120.

The buffer layer 150 may be additionally provided for excellent bonding because differences of lattice constants and energy bandgaps between the light absorbing layer 140 and the front transparent electrode 160 are large. It may be preferable that the buffer layer 150 has an energy bandgap between those of the light absorbing layer 140 and the transparent electrode 160.

For example, the buffer layer 150 may be formed of a CdS thin film, a ZinS thin film, or an InₓSe_{y} thin film. The CdS thin film may be formed of a thickness of about 500 Å. The CdS thin film has an energy bandgap of about 2.46 eV and this corresponds to a wavelength of about 550 nm The CdS thin film is an n-type semiconductor and may be doped with In, Ga, and Al to obtain a low resistance value. The buffer layer 150 may be omitted.

The front transparent electrode 160 may be formed of a material having a high light transmittance and excellent electrical conductivity. For example, the front transparent electrode 160 may be formed of a ZnO thin film. The ZnO thin film has an energy bandgap of about 3.3 eV and a high light transmittance of about 80%. The ZnO thin film may be doped with Al or B to have a low resistance value.

Unlike this, the front transparent electrode 160 may be formed by stacking an ITO thin film having excellent electrical-optical characteristic on the ZnO thin film or may be formed with a single layer of an ITO thin film. Moreover, the front transparent electrode 160 may be formed by stacking an n-type ZnO thin layer having a low resistance on an undoped i-type ZnO thin film. The front transparent electrode 160 as an n-type semiconductor and the light absorbing layer 140 as a p-type semiconductor form a pn junction.

The anti-reflection layer 170 may reduce reflection loss of the solar light incident to the solar cell 100. Efficiency of the solar cell 100 may be improved by the anti-reflection layer 170. As one example, the anti-reflection layer may be formed of a MgF₂ thin film. Additionally, the anti-reflection layer 170 may be omitted.

The grid electrode 180 may be provided at one side of the anti-reflection layer 170 in contact with the front transparent electrode 160. The grid electrode 180 may collect current at the surface of the solar cell 100. The grid electrode 180 may be formed of metal such as Al or Ni/Al. Since solar light is not incident to a portion that the grid electrode 180 occupies, a size of the grid electrode 180 may need to be minimized

Current flows in the CIGS based thin film solar cell 100 when a load is connected to the rear electrode 130 and the front transparent electrode 160 at both ends.

According to an embodiment of the present invention, since the impurity diffusion preventing layer 120 including the metal layer 120a with the added alkali component is interposed below the rear electrode 130, impurity of the substrate 110 is prevented from diffusing into the light absorbing layer 140 and the alkali component 120b added to the impurity diffusion preventing layer 120 selectively diffuses into the light absorbing layer 140, so that efficiency of the solar cell 100 may be improved. Additionally, the substrate 110 is not limited to sodalime glass and thus may include various kinds of materials.

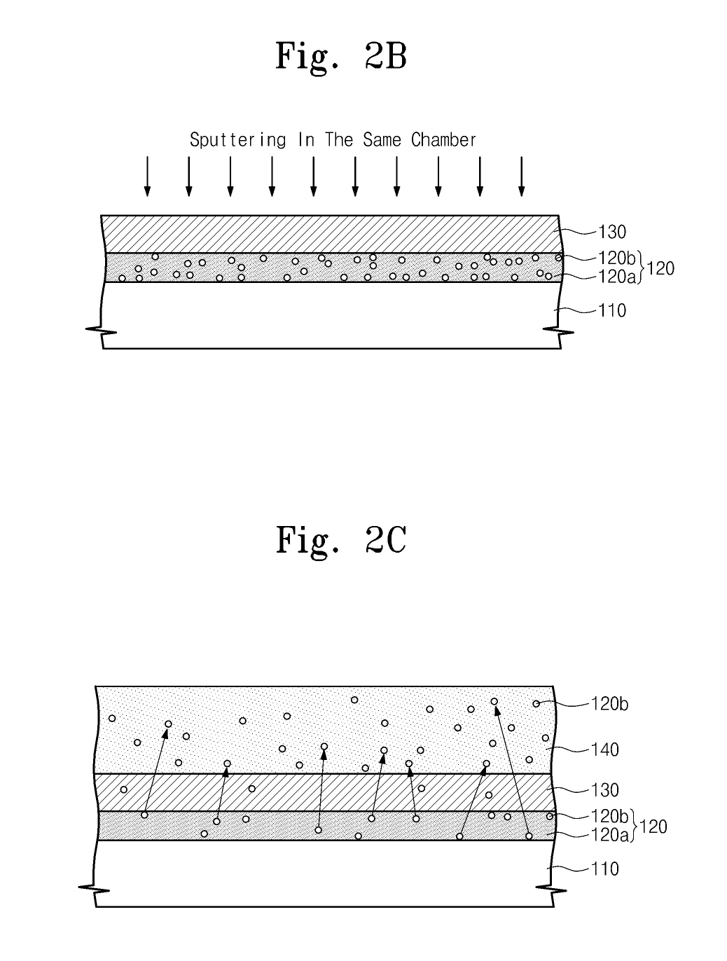

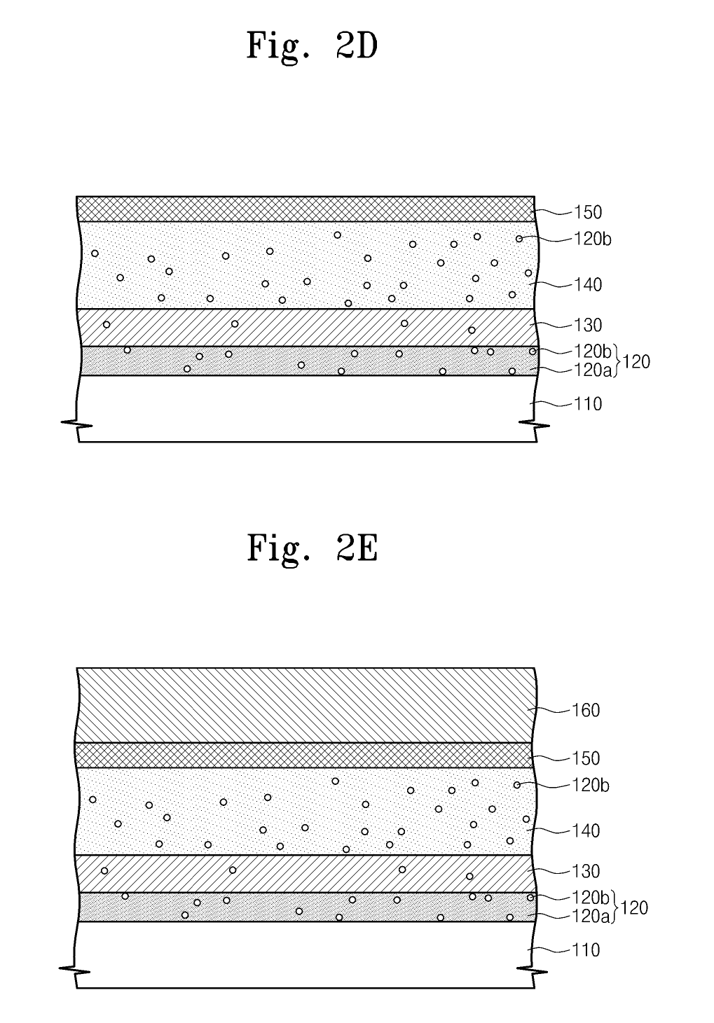

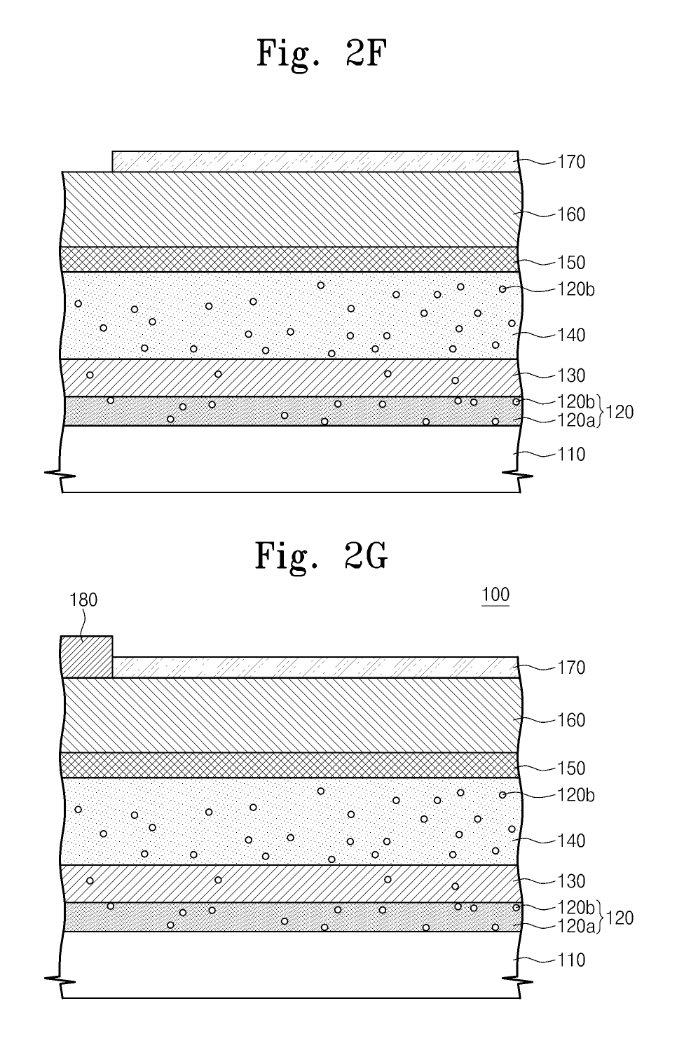

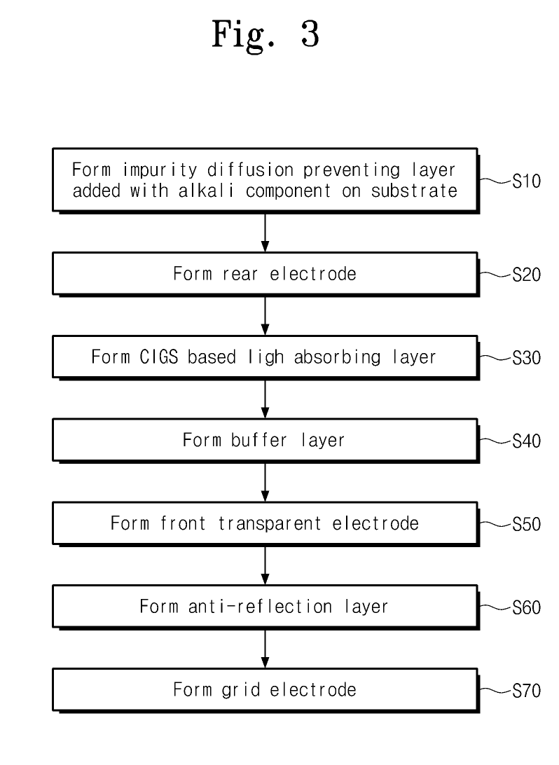

FIGS. 2A through 2G are sectional views illustrating a method of manufacturing a CIGS based thin film solar cell according to an embodiment of the present invention. FIG. 3 is a flowchart illustrating a method of manufacturing a CIGS based thin film solar cell according to an embodiment of the present invention.

Referring to FIG. 2A and 3, an impurity diffusion preventing layer 120 may be formed on a substrate 110 in operation S10. The substrate 110 may be a sodalime glass substrate. The sodalime glass substrate is known as a relatively cheap substrate material. Additionally, natrium (Na) of the sodalime glass substrate diffuses into the CIGS based light absorbing layer 140 of FIG. 2C to improve photoelectric conversion efficiency of the solar cell 100 of FIG. 2G.

As another example, the substrate 110 may be a ceramic substrate such as alumina (Al₂O₃) and quartz, a metal substrate such as stainless steel, Cu tape, Cr steel, Kovar (i.e., an alloy of Ni and Fe), Ti, ferritic steel, and Mo, or a polymer film such as a Kapton, polyester or polyimide film (e.g., Upilex, ETH-PI). The substrate 110 may typically use the sodalime glass substrate where an alkali component such as Na may diffuses into the light absorbing layer 140 during the manufacturing of the CIGS based light absorbing layer 140, but the present invention is not limited to the sodalime glass substrate with an alkali component 120b in the impurity diffusion preventing layer 120 and may use a substrate without the alkali component 120b.

The impurity diffusion preventing layer 120 may serve to prevent impurity from diffusing from a supply source of the alkali component 120b and the substrate 110 to the light absorbing layer 140.

As one example, the impurity diffusion preventing layer 120 may be formed of a metal layer 120a for preventing impurity diffusion with the alkali component 120b. The stainless steel used typically for a flexible substrate contains an impurity such as Fe and, since Mo used for the rear electrode 130 of FIG. 2B may not prevent the impurity from diffusing into the light absorbing layer 140 during a manufacturing process of the light absorbing layer 140, the impurity diffusion preventing layer 120 may be interposed. Especially, it may expect to some extent that the thick thickness of Mo may prevent impurity diffusion, but due to its expensive price, it is undesirable when considering manufacturing costs.

The metal layer 120a may include one of Cr, Co, and Cu. Cr, Co, and Cu are relatively cheaper than Mo and have excellent impurity diffusion preventing function to thickness.

The alkali component 120b may be at least one of Li, Na, K, Rb, Cs, Fr, N, P, As, Sb, Bi, V, Nb, and Ta. The alkali component 120b may be appropriately selected in consideration of manufacturing cost, crystalline relationship to the CIGS based light absorbing layer 140, and activation as impurity. The alkali component 120b may be Li, Na or K, and Na is more preferable. The alkali component 120 may diffuse into the light absorbing layer 140 to increase photoelectric conversion efficiency of the CIGS based thin film solar cell 100. This is because the alkali component 120b forms an organization of the CIGS thin film better, serves as a protective layer in a grain boundary, improves p-type electrical conductivity, and reduces defects of the CIGS thin film.

The impurity diffusion preventing layer 120 may be formed of a thickness of about 0.01 μm to about 10 μm to prevent impurity from diffusing from the substrate 110 and realize a thin film solar cell.

The content of the alkali component 120b added to the impurity diffusion preventing layer 120 may vary according to a thickness, composition, and manufacturing process of the light absorbing layer 140. If the alkali component 120b added to the impurity diffusion preventing layer 120 is excessive, it serves as an impurity so that interlayer adhesion and efficiency of the solar cell 100 may be deteriorated. On the other hand, if the alkali component 120b added to the impurity diffusion preventing layer 120 is too little, desirable crystal growth to the CIGS thin layer and efficiency improvement of the solar cell 100 may not be obtained. Accordingly, the content of the alkali component 120b added to the impurity diffusion preventing layer 120 may be about 0.1 atom % to about 50 atom % to the total weight of the metal layer 120a.

The impurity diffusion preventing layer 120 may be formed through a sputtering method using one of impurity diffusion preventing metals with the added alkali component 120b as a target. For example, the sputtering method may be typical Direct Current (DC) sputtering method. At this point, a temperature of the substrate 110 may be a room temperature.

Referring to FIGS. 2B and 3, a rear electrode 130 may be formed on the impurity diffusion preventing layer 120 in operation S20. The rear electrode 130 may have a low resistivity and excellent formation characteristic of ohmic contact with the CIGS based light absorbing layer 140.

Preferably, the rear electrode 130 may be formed of Mo. Mo has high temperature stability under high electrical conductivity and Se atmosphere, and a de-lamination phenomenon does not occur due to a difference of a thermal expansion coefficient with respect to the CIGS based light absorbing layer 140.

The rear electrode 130 may be formed through a sputtering method in the same chamber where the impurity diffusion preventing layer 120 is deposited using a material containing Mo as a target. For example, the sputtering method may be typical DC sputtering method. At this point, a temperature of the substrate 110 may be a room temperature.

Since the rear electrode 130 is formed of the same metal as the impurity diffusion preventing layer 120, pollution due to metal may be prevented so that the rear electrode 130 may be manufactured in the same chamber where the impurity diffusion preventing layer 120 is deposited. Accordingly, through the savings of equipment installation cost, manufacturing costs of the solar cell 100 may be reduced. Furthermore, since an in-situ process is possible, Turn Around Time (TAT) may be shortened, thereby improving the productivity.

Referring to FIGS. 2C and 3, a CIGS based light absorbing layer 140 may be formed on the rear electrode 130 in operation S30. The light absorbing layer 140 may be formed of a GROUP I-III-VI₂ compound semiconductor. The GROUP I-III-VI₂ compound semiconductor may be a chalcopyrite based compound semiconductor such as CuInSe, CuInSe₂, CuInGaSe, CuInGaSe₂, AgCuInGaSe₂, AgCuInGaSe₂, CuInGaSSe₂, and CuInGaS₂. These compound semiconductors may be commonly named as CIGS based thin films.

Preferably, the light absorbing layer 140 may be formed of CuInGaSe₂, which has an energy bandgap of about 1.2 eV close to the maximum efficiency of a polycrystalline solar cell of a typical wafer form in a single bonding solar cell.

The light absorbing layer 140 may be formed through a physical method or a chemical method. As one example, the physical method may be an evaporation method or a mixed method of sputtering and a selenization process. As one example, the chemical method may be an electroplating method.

The physical or chemical method may be various manufacturing methods according to kinds of starting materials (metal and binary compound).

Preferably, the light absorbing layer 140 may be formed through a co-evaporation method using a metallic element of Cu, In, Ga, and Se as a starting material.

Unlike this, the light absorbing layer 140 may be formed by synthesizing a nano-sized particle (powder and colloid) on the rear electrode 130, mixing the synthesized result with a solvent, performing screen printing, and then performing reaction sintering.

During the forming of the light absorbing layer 140, a temperature of the substrate 100 may be about 400° C. to about 600° C. Like this, since the substrate 110 is at a high temperature during the forming of the light absorbing layer 140, a portion of the alkali component 120b added to the impurity diffusion preventing layer 120 may diffuse into the light absorbing layer 140. However, impurities (not shown) in the substrate 110 may not diffuse into the light absorbing layer 140 by the impurity diffusion preventing layer 120.

Referring to FIGS. 2D and 3, a buffer layer 150 may be formed on the light absorbing layer 140 in operation S40. The buffer layer 150 may be additionally provided for excellent bonding because differences of lattice constants and energy bandgaps between the light absorbing layer 140 and the front transparent electrode 160 are large. An energy bandgap of the buffer layer 150 may be disposed on the middle of that between the light absorbing layer 140 and the transparent electrode 160.

For example, the buffer layer 150 may be formed of a CdS thin film, a ZinS thin film, or an InₓSe_{y} thin film. The CdS thin film and the ZnS thin film may be formed through a Chemical Bath Deposition (CBD) or a sputtering method. The CdS thin film may be formed of a thickness of about 500 Å.

The CdS thin film may have an energy bandgap of about 2.46 eV corresponding to a wavelength of about 550 nm. The CdS thin film is an n-type semiconductor and may be doped with In, Ga, and Al to obtain a low resistance value. The buffer layer 150 may be omitted.

The InₓSe_{y} thin film may be formed through a physical method. The physical method may be a sputtering method or a co-evaporation method. Moreover, the buffer layer 150 may be omitted.

Referring to FIGS. 2E and 3, a front transparent electrode 160 may be formed on the buffer layer 150 in operation S50. The front transparent electrode 160 may be formed of high light transmittance and excellent electrical conductivity.

For example, the front transparent electrode 160 may be formed of a ZnO thin film. The ZnO thin film has an energy bandgap of about 3.3 eV and a high light transmittance of more than about 80%. Here, the ZnO thin film may be formed through a Radio Frequency (RF) sputtering method using a ZnO target, a reactive sputtering method using a Zn target, or an organic metal chemical vapor deposition method. The ZnO thin film may be doped with Al or B to have a low resistance value.

Unlike this, the front transparent electrode 160 may be formed by stacking an ITO thin film having excellent electrical-optical characteristic on the ZnO thin film or may be formed with a single layer of an ITO thin film. Moreover, the front transparent electrode 160 may be formed by stacking an n-type ZnO thin layer having a low resistance on an undoped i-type ZnO thin film. The ITO thin film may be formed through a typical sputtering method. The front transparent electrode 160 as an n-type semiconductor and the light absorbing layer 140 as a p-type semiconductor form a pn junction.

Referring to FIGS. 2F and 3, an anti-reflection layer 170 may be formed in one region on the front transparent electrode 160 in operation S60. The anti-reflection layer 170 may reduce reflection loss of the solar light incident to the solar cell 100. Efficiency of the solar cell 100 may be improved by the anti-reflection layer 170. As one example, the anti-reflection layer may be formed of a MgF₂ thin film. Additionally, the anti-reflection layer 170 may be omitted.

Referring to FIGS. 2G and 3, a grid electrode 180 may be formed on the front transparent electrode 170 at one side of the anti-reflection layer 170 in operation S70, so that the CIGS based thin film solar cell 100 may be completed. The grid electrode 180 may collect current at the surface of the solar cell 100. The grid electrode 180 may be formed of metal such as Al or Ni/Al. The grid electrode 180 may be formed through a sputtering method. Since solar light is not incident to a portion that the grid electrode 180 occupies, its size needs to be minimized

According to an embodiment of the present invention, since the metal layer 120a of an impurity diffusion preventing function with the added alkali component 120b is used as the impurity diffusion preventing layer 120 and this is formed in the same chamber where the rear electrode 130 is formed, so that manufacturing costs of the solar cell 100 may be reduced. The impurity of the substrate 110 is prevented from diffusing into the light absorbing layer 140 and the alkali component 120b added to the impurity diffusion preventing layer 120 diffuses into the light absorbing layer 140, so that efficiency of the solar cell 100 may be improved.

According to an embodiment, the metal layer 120a containing alkali component 120b for impurity diffusion preventing function is used as an impurity diffusion preventing layer 120 and this is manufactured together with the rear electrode 130 in the same chamber. Therefore, manufacturing cost of the solar cell 100 may be reduced and efficiency of the solar cell 100 may be improved since impurities of the substrate 110 are prevented from diffusing into the light absorbing layer 140 and the alkali component 120b in the impurity diffusion preventing layer 120 diffuses into the light absorbing layer 140. Additionally, the substrate 110 is not limited to a sodalime glass and may include various kinds of substrates.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A compound semiconductor solar cell comprising:
an impurity diffusion preventing layer disposed on a substrate, added with an alkali component, and formed of a metal layer of one of Cr, Co, or Cu;
a rear electrode disposed on the impurity diffusion preventing layer and formed of Mo;
a CIGS based light absorbing layer disposed on the rear electrode; and
a front transparent electrode disposed on the light absorbing layer.

2. The compound semiconductor solar cell of claim 1, wherein the alkali component comprises at least one of Li, Na, K, Rb, Cs, Fr, N, P, As, Sb, Bi, V, Nb, and Ta.

3. The compound semiconductor solar cell of claim 1, wherein a content of the alkali component added to the impurity diffusion preventing layer is about 0.1 atomic % to about 50 atomic % to a total atomic weight of the metal layer.

4. The compound semiconductor solar cell of claim 1, wherein the impurity diffusion preventing layer has a thickness of about 0.01 μm to about 10 μm.

5. The compound semiconductor solar cell of claim 1, wherein the light absorbing layer comprises a GROUP I-III-VI₂ compound semiconductor.

6. The compound semiconductor solar cell of claim 5, wherein the light absorbing layer comprises the alkali component diffusing from the impurity diffusion preventing layer.

7. The compound semiconductor solar cell of claim 1, wherein the substrate comprises one of a sodalime glass substrate, a ceramic substrate, a metal substrate, and a polymer film.

8. The compound semiconductor solar cell of claim 1, further comprising a buffer layer between the light absorbing layer and the front transparent electrode.

9. The compound semiconductor solar cell of claim 1, further comprising:
an anti-reflection layer disposed in one region on the front transparent electrode; and
a grid electrode disposed at a side of the anti-reflection layer in contact with the front transparent electrode.

10. A method of manufacturing a compound semiconductor solar cell, the method comprising:
forming an impurity diffusion preventing layer disposed on a substrate, added with an alkali component, and formed of a metal layer of one of Cr, Co, and Cu;
forming a rear electrode disposed on the impurity diffusion preventing layer and formed of Mo;
forming a CIGS based light absorbing layer disposed on the rear electrode; and
forming a front transparent electrode disposed on the light absorbing layer.

11. The method of claim 10, wherein the impurity diffusion preventing layer is formed through a sputtering method.

12. The method of claim 11, wherein the rear electrode is formed through the sputtering method in the same chamber as the impurity diffusion preventing layer.
